(19) United States
(12) Patent Application Publication
(10) Pub. No.: US 2026/0314082 A1
(43) Pub. Date: Oct. 8, 2026

(54) SEMICONDUCTOR INTEGRATED CIRCUIT DEVICE INCLUDING PLASMA INDUCED DAMAGE PROTECTION DEVICE

(71) Applicant: SK hynix Inc., Gyeonggi-do (KR)

(72) Inventors: Inseon YOON, Gyeonggi-do (KR); Seok HUH, Gyeonggi-do (KR)

(21) Appl. No.: 19/243,609

(22) Filed: Jun. 19, 2025

(30) Foreign Application Priority Data
Apr. 8, 2025 (KR) 10-2025-0045449

(51) Int. Cl. H10D 89/60

(52) U.S. Cl. CPC H10D 89/931; H10D 89/611; H10D 89/813; H10D 89/921

(57) ABSTRACT

A semiconductor integrated circuit device for discharging plasma induced charges includes a protection transistor, a first discharging element and a second discharging element. The protection transistor is connected to a first wiring structure. At least one of a gate voltage and a plasma induced charge is provided to the protection transistor. The first discharging element is connected to a second wiring structure electrically connected to the first wiring structure. The first discharging element discharges a plasma induced negative charge introduced through the second wiring structure. When the plasma induced positive charge is introduced into the second discharge unit via a third wiring structure electrically connected to the second wiring structure, the second discharging element discharges the plasma induced positive charge. When a gate voltage is applied through the third wiring structure, the second discharging element is electrically isolated from the third wiring structure.

### CROSS-REFERENCES TO RELATED APPLICATION

The present application claims priority under 35 U.S.C. § 119(a) to Korean patent application number 10-2025-0045449, filed on Apr. 8, 2025, which is incorporated herein by reference in its entirety.

### BACKGROUND

### 1. Technical Field

Example embodiments relate to a semiconductor integrated circuit device, and more particularly to a semiconductor integrated circuit device including a plasma induced damage protection device.

### 2. Related Art

As the integration density of semiconductor devices have increased, there has been an increasing demand for plasma processes. The plasma processes may include various processes such as a plasma enhanced chemical vapor deposition (PECVD), a plasma etching and a plasma cleaning.

However, during plasma processes, an ion bombardment and a penetration of etching species into a substrate may cause charges to be trapped on a wafer or cause damage to insulation layers formed over the wafer. This phenomenon is known as plasma induced damage (PID), which may degrade a performance of semiconductor integrated circuits.

### SUMMARY

Example embodiments provide a semiconductor integrated circuit device capable of effectively discharging plasma induced charges without increasing an area of a PID protection device.

According to example embodiments, there may be provided a semiconductor integrated circuit device. The semiconductor integrated circuit device may include a protection transistor, a first discharging element and a second discharging element.

The protection transistor may be connected to a first wiring structure, and configured to receive at least one of a gate voltage and plasma induced charges.

The first discharging element may be connected to a second wiring structure electrically coupled to the first wiring structure. The first discharging element may discharge a plasma inducted negative charge introduced through the second wiring structure.

The second discharging element may be configured to discharge a plasma induced positive charge through a third wiring structure electrically connected to the second wiring structure.

In example embodiments, at least one of the first discharging element and second discharging element may include a blocking pattern configured to block a leakage current in accordance with to the gate voltage during operation of the protection transistor when the gate voltage may be applied.

According to example embodiments, there may be provided a semiconductor integrated circuit device. The semiconductor integrated circuit device may include a semiconductor substrate, a first well, a protection transistor, a first discharging element and a second discharging element. The first well may be formed in the semiconductor substrate. The first well may have a first conductive type. The protection transistor may be integrated in the first well. The first discharging element may include a reverse diode integrated into the first well. The second discharging element may include a pseudo-junction diode and a blocking pattern. The pseudo-junction diode may be integrated into the first well. The blocking pattern having an insulating material may be configured to cover the pseudo- junction diode.

According to example embodiments, there may be provided a semiconductor integrated circuit device. The semiconductor integrated circuit device may include a charged semiconductor substrate, a first well, a second well, a protection transistor, a first discharging element and a second discharging element. The first well having a first conductive type may be formed in the semiconductor substrate. The second well having a second conductive type may be formed in the semiconductor substrate adjacent to the first well. The protection transistor may be formed in the first well. The first discharging element may include a reverse diode integrated into the first well. The second discharging element may include a forward diode and a blocking pattern. The forward diode may be integrated in the second well. The blocking pattern having an insulating material may be configured to cover the forward diode.

According to example embodiments, the semiconductor integrated circuit device for discharging a plasma induced charge may include the protection transistor, the first discharging element for discharging the plasma induced negative charge, and the second discharging element for discharging ae plasma induced positive charge.

The second discharging element may include a high concentration P-type impurity region formed in a p-well in which a floated n-well or the protection transistor and the first discharging element may be integrated, and the blocking pattern configured to cover an upper portion of the high concentration P-type impurity region.

When the high concentration p-type impurity region is formed in the n-well, the n-well may not be needed to be included with an n-well pickup region for applying a voltage to the n-well, so that the plasma induced positive charge may be effectively discharged without expanding an area of the semiconductor integrated circuit device.

When the high concentration p-type impurity region is formed in the p-well, the protection transistor and the first discharging element may be formed in the same p-well, thereby reducing the area of the semiconductor integrated circuit device.

On the other hand, when the protection transistor is operated, even if the gate voltage of the protection transistor is applied to the second discharging element, the applying of the gate voltage to the high concentration p-type impurity region may be blocked by the blocking pattern.

Accordingly, the plasma induced positive and negative charges may be effectively discharged when the protection transistor may not be driven, without increasing the occupied area.

### BRIEF DESCRIPTION OF THE DRAWINGS

The above and another aspects, features and advantages of the subject matter of the present disclosure will be more easily understood from the following detailed description taken in conjunction with the accompanying drawings, in which:

FIG. 1 is a circuit diagram illustrating a PID protection device, in accordance with an embodiment of the present disclosure;

FIG. 2 is a circuit diagram illustrating a PID protection device, in accordance with an embodiment of the present disclosure;

FIG. 3 is a layout diagram illustrating the PID protection device in FIG. 2, in accordance with an embodiment of the present disclosure;

FIG. 4 is a cross-sectional view of a semiconductor integrated circuit device taken along a line A-A' of FIG. 3, in accordance with an embodiment of the present disclosure;

FIG. 5 is a circuit diagram illustrating a PID protection device, in accordance with an embodiment of the present disclosure;

FIG. 6 is a layout diagram illustrating the PID protection device in FIG. 5, in accordance with an embodiment of the present disclosure;

FIG. 7 is a cross-sectional view of a semiconductor integrated circuit device taken along a line B-B' of FIG. 5, in accordance with an embodiment of the present disclosure; and

FIGS. 8 and 9 are cross-sectional views illustrating semiconductor integrated circuit devices, in accordance with an embodiment of the present disclosure.

### DETAILED DESCRIPTION

The advantages and features of the present invention, and methods of achieving them, will become apparent upon reference to the embodiments described in detail with reference to the accompanying drawings. However, the present invention is not limited to the embodiments disclosed herein, but will be embodied in many different forms, and these embodiments are provided merely to make the disclosure of the invention complete, and to fully inform those of ordinary skill in the art to which the invention belongs, of the scope of the invention, which is defined by the claims. The dimensions and relative sizes of the layers and regions in the drawings may be exaggerated for clarity of description. Throughout the specification, like reference numerals refer to like components.

FIG. 1 is a circuit diagram illustrating a plasma induced damage (PID) protection device 10 in accordance with example embodiments.

Referring to FIG. 1, the PID protection device 10 may include a protection transistor 20, a first discharging element 30, and a second discharging element 40.

In example embodiments, the protection transistor 20 may include an NMOS transistor. The protection transistor 20 may include a gate, a source, a drain and a body. The gate of the protection transistor 20 may receive a gate voltage VH. For example, the gate voltage VH may have a voltage level of a pumping voltage. The source of the protection transistor 20 may be connected to a source voltage terminal. The drain of the protection transistor 20 may be connected to a drain voltage terminal. For example, the source voltage terminal may receive a ground voltage. The drain voltage terminal may receive a power supply voltage Vd. The body of the protection transistor 20 may correspond to a first conductive well, such as a p-well. The p-well may receive a well voltage Vw. For example, the p-well may be grounded.

The first discharging element 30 may discharge one (charge) selected from a plasma induced negative charge and a plasma induced positive charge. In example embodiments, when the protection transistor 20 may be turned off, the first discharging element 30 may discharge the plasma inducted negative charge of the plasma induced charges. The first discharging element 30 may be electrically connected to the gate of the protection transistor 20. For example, the first discharging element 30 may include a reverse diode. Accordingly, when the protection transistor 20 is turned on, the first discharging element 30 may not be driven. On the other hand, when the protection transistor 20 is turned off, the plasma induced negative charge may be introduced into the first discharging element 30 so that the reverse diode may be driven, thereby discharging the plasma induced negative charge into an anode of the reverse diode. The anode of the first discharging element 30 may be (for example, selected as a) p-well to receive the well voltage Vw.

The second discharging element 40 may discharge a remaining one of the plasma induced negative charge and the plasma induced positive charge. For example, when the protection transistor 20 is turned off, the second discharging element 40 may discharge the plasma induced positive charge. For example, the second discharging element 40 may be covered by a blocking pattern (not shown) including an insulation material. Accordingly, conductive elements of the second discharging element 40 may be substantially isolated from a conductive line for transmitting the gate voltage. Therefore, when the protection transistor 20 is turned on, the second discharging element 40 may also not be driven. On the other hand, when the protection transistor 20 is turned off, the plasma induced positive charge may flow past the blocking pattern into the conductive elements of the second discharging element 40. In example embodiments, the second discharging element 40 may include a forward diode or a junction diode with the same conductive type to discharge the plasma induced charge to the anode of the forward diode. In example embodiments, when the second discharging element 40 includes the forward diode, the anode may correspond to an n-well, and the anode may be floated. In another example embodiment, when the second discharging element 40 includes a junction diode, the anode may correspond to a p-well, and the anode may receive the well voltage Vw.

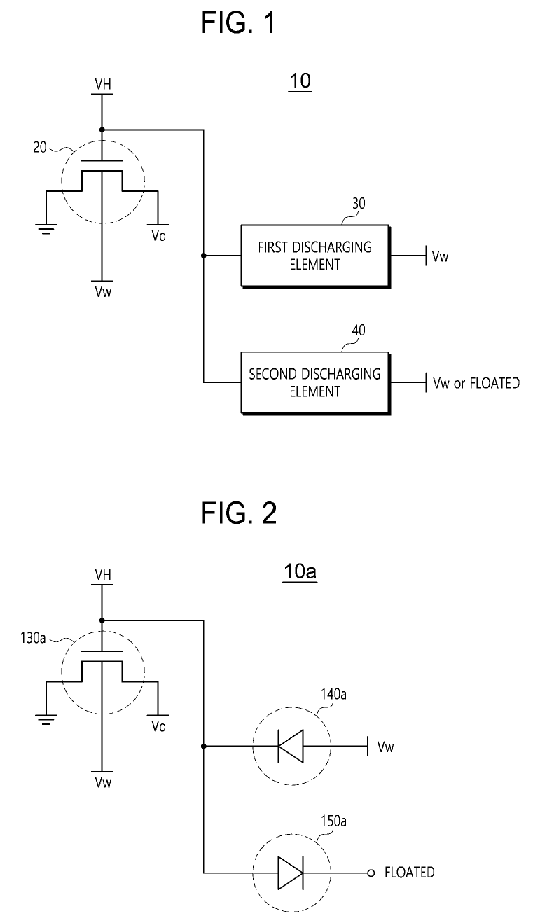

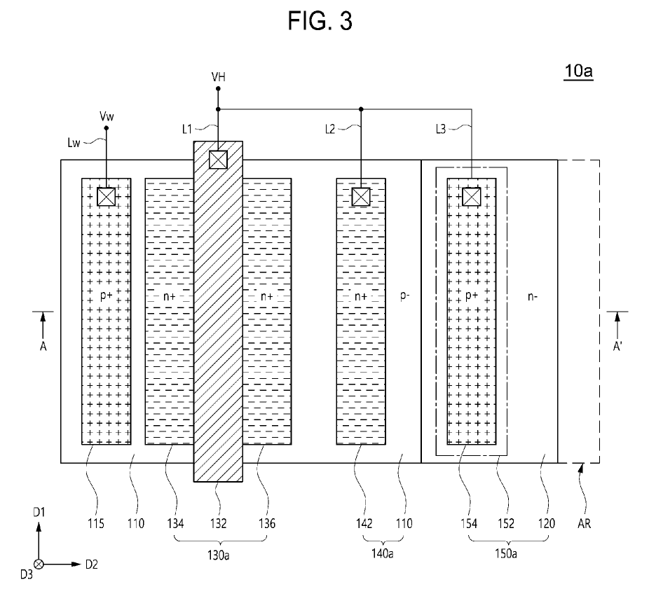

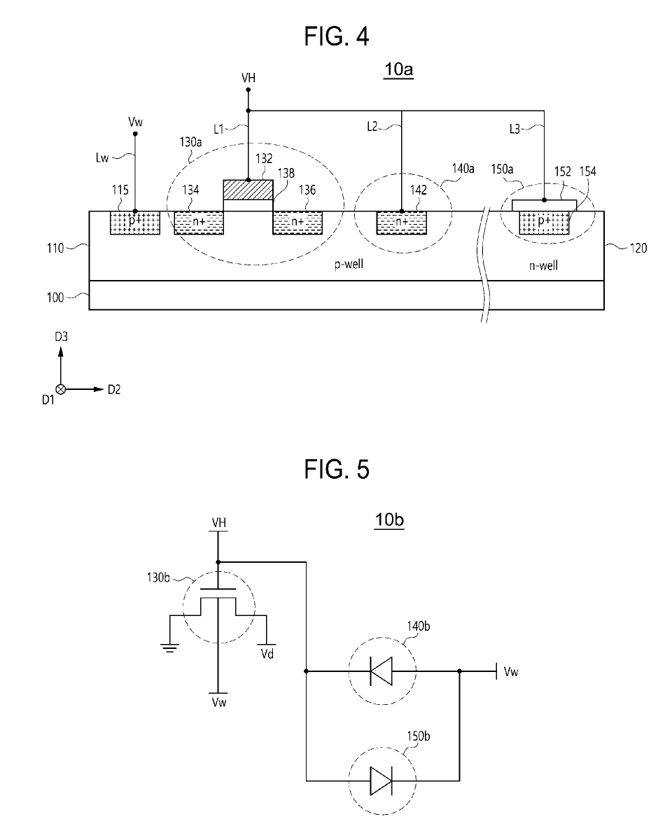

FIG. 2 is a circuit diagram illustrating a PID protection device 10a in accordance with example embodiments. FIG. 3 is a layout diagram illustrating the PID protection device 10a of FIG. 2. FIG. 4 is a cross-sectional view of a semiconductor integrated circuit device taken along a line A-A' of FIG. 3.

Referring to FIGS. 2 to 4, the PID protection device 10a may include a protection transistor 130a, a first discharging element 140a and a second discharging element 150a.

The PID protection device 10a may be integrated into a selected region of the semiconductor substrate 100. For example, the selected region of the semiconductor substrate 100 may include a first conductive well, and a second conductive well opposite to the first conductive well. The first conductive well may include a p-well 110, and the second conductive well may include an n-well 120.

The protection transistor 130a and the first discharging element 140a may be integrated into the p-well 110. The second discharging element 150a may be integrated into the n-well 120. Accordingly, the p-well 110 may be formed to have a relatively larger area than the n-well 120.

The p-well 110 may include low concentration p-type impurities. In order to provide a voltage to the p-well 110, a p-well pickup region 115 may be formed in a predetermined region of the p-well 110, for example, at a selected edge of the p-well 110. Since the p-well pickup region 115 may be a region for applying the well voltage Vw to the p-well 110, the p-well pickup region 115 may be formed in various sizes and various types, while having the same impurity type as the p-well 110. The p-well pickup region 115 may be in contact with a well pickup line Lw configured to transmit the well voltage Vw. The p-well pickup region 115 may include a higher concentration of p-type impurities P+ than the p-well 110. Accordingly, the p-well 110 may receive the well voltage Vw via the well pickup line Lw and the p-well pickup region 115. The well voltage Vw may be, for example, a ground voltage.

The n-well 120 may be located at a side portion of the p-well 110. The n-well 120 may include low concentration N-type impurities n-.

The protection transistor 130a may be integrated in the p-well 110 between the p-well pickup region 115 and the first discharging element 140a.

A gate 132 of the protection transistor 130a may be disposed on the p-well 110. The gate 132 may have a line type, for example, and may extend along a first direction D1. The gate 132 may include a conductive material, for example, a metal. The gate 132 may be provided with a gate voltage VH via a first wiring structure L1. For example, the first wiring structure L1 may include at least one horizontal wiring and at least one vertical wiring. Further, at least one insulating interlayer (not shown) may be positioned between the horizontal wiring and the vertical wiring in the first wiring structure L1. The horizontal wiring, the vertical wiring and the insulating interlayer may be fabricated, for example, by a deposition process, an etching process, and a cleaning process using plasma. Accordingly, plasma induced charges may be generated during the deposition process, the etching process, and the cleaning process, which may be retained in the horizontal wiring, the vertical wiring, and the insulating interlayer.

The source 134 may be formed in the p-well 110 on one side of the gate 132. The drain 136 may be formed in the p-well 110 on the other side of the gate 132. In example embodiments, the source 134 may be disposed closer to the p-well pickup region 115 than the drain 136. Each of the source 134 and the drain 136 may include a high concentration of N-type impurities n+. Accordingly, the protection transistor 130a may include an NMOS transistor.

The protection transistor 130a may further include a gate insulation layer 138. The gate insulation layer 138 may be positioned between the gate 132 and the p-well 110 corresponding to the body of the protection transistor 130a. The protection transistor 130a may be a measuring element for measuring effects of the plasma induced charges in a semiconductor integrated circuit device. The protection transistor 130a may be driven at a high voltage having a positive voltage level, for example, a voltage of about 3V to about 4V. Accordingly, the gate insulation layer 138 may have a thickness capable of withstanding the high voltage, for example, from about 40µm to about 70µm in thickness. Accordingly, the plasma induced charges may accumulate on the gate insulation layer 138 before the gate voltage VH may be received at the gate of the protection transistor 130a.

Although not shown in drawings, the source 134 of the protection transistor 130a may receive a source voltage, such as a ground voltage, and the drain 136 may receive a power voltage.

The first discharging element 140a may be integrated into the p-well 110 corresponding to a side portion of the protection transistor 130a (e.g., on a second direction D2 side of the drawing). For reference, a third direction D3 in the drawing may indicate a stacking direction. The first discharging element 140a may include a high concentration n-type impurity region 142 formed in the p-well 110. Accordingly, the first discharging element 140a may have a reverse diode structure. In example embodiments, the high concentration n-type impurity region 142 may be a cathode of the reverse diode, and the p-well 110 may be an anode of the reverse diode.

The second discharging element 150a may include a blocking pattern 152, and a high concentration p-type impurity region 154, which is disposed on the n-well 120.

The blocking pattern 152 may be formed on the n-well 120 to cover the high concentration p-type impurity region 154. The blocking pattern 152 may include an insulation pattern having a thickness less than the gate insulation layer 138. The blocking pattern 152 may be in contact with a third wiring structure L3 electrically connected to the first and second wiring structures L1 and L2. For example, the blocking pattern 152 may electrically isolate the third wiring structure L3 from the high concentration p-type impurity region 154.

The high concentration p-type impurity region p+ 154 may be formed in the n-well 120. Accordingly, the high concentration p-type impurity region 154 and the n-well 120 corresponding to the conductive elements of the second charge part 150a may have a forward diode.

In example embodiments, the n-well 120 may be in a floating state. Accordingly, the second discharging element 150a may not require an n-well pickup area. Thus, an area of the second discharging element 150a in example embodiments may have a significantly smaller area than an n-well including the n-well pickup area. In FIG. 3, a reference numeral "AR" may indicate an area reduced by the omission of the n-well pickup area.

For reference, although not shown in drawings, a device isolation layer may be provided between the protection transistor 130a, the first discharging element 140a and the second discharging element 150a.

The PID protection device 10a may be operated as follows.

The plasma induced charges remaining in the insulating interlayer (not shown) due to the plasma process may be introduced into the protection transistor 130a, the first discharging element 140a, and the second discharging element 150a along the first to third wiring structures L1-L3 located in the insulating interlayer.

For example, the plasma induced charges loaded into the first wiring structure L1 may be trapped in the gate insulation layer 138 through the gate 132 of the protection transistor 130a.

Additionally (for example, concurrently), the plasma induced charges may be introduced into the high concentration n-type impurity region 142 of the first discharging element 140a via a second wiring structure L2. Consequently, the plasma induced negative charge may act as a positive bias to turn on the first discharging element 140a having the reverse diode. By the reverse diode operation of the first discharging element 140a, the plasma induced negative charge may be transferred to the p-well 110. Since the p-well 110 may receive the well voltage Vw, such as the ground voltage, the plasma induced negative charge may be discharged.

The plasma induced charges may be transferred to the second discharging element 150a via a third wiring structure L3. The plasma induced positive charge may be introduced to (e.g., flow into) the high concentration p-type impurity region 154 by tunneling through the blocking pattern 152. The forward diode may be formed between the high concentration p-type impurity region 154 and the n-well 120 of the second discharging element 150b, so that the plasma induced positive charge may be electro-migrated to the n-well 120.

For example, in example embodiments, the tunneling of the blocking pattern 152 may refer to the phenomenon of the plasma induced charges tunneling through the blocking pattern 152 with a sufficiently small thickness (for example, sufficient thinness) for the plasma induced charges to be transferred to the high concentration p-type impurity region 154.

Even though the n-well 120 may be floated, the semiconductor substrate 100 on which the n-well 120 may be formed may include conductive impurities, and in order to fabricate a semiconductor integrated circuit device, the process may proceed with an electrostatic wafer chuck. Accordingly, the semiconductor substrate 100 may be charged by the electrostatic wafer chuck, and the plasma induced positive charge electro-migrated to the n-well 120 may be discharged through the charged semiconductor substrate and the charged wafer chuck configured to support the semiconductor substrate.

On the other hand, in order to drive the protection transistor 130a, when the gate voltage VH may be applied to the gate 132 of the protection transistor 130a via the first wiring structure L1, the protection transistor 130a may be turned on. Through an output current of the protection transistor 130a, an amount of the plasma induced charges accumulated on the gate insulation layer 138 may be measured.

The gate voltage VH may be transmitted to the first and second discharging elements 140a and 150a via the first wiring structure L1 as well as via the second and third wiring structures L2 and L3.

When the gate voltage VH may be provided to the first discharging element 140a via the second wiring structure L2, the first discharging element 140a may not be driven.

Further, the third wiring structure L3 for transferring the gate voltage VH and the high concentration p-type impurity region 154 may be mutually isolated by the blocking pattern 152. Therefore, the second discharging element 140a may also not be driven.

Accordingly, the second discharging element 150a may discharge the plasma induced positive charge without including the n-well pickup region, and the operation of the second discharging element 150a may be stopped when the protection transistor 130a is turned on.

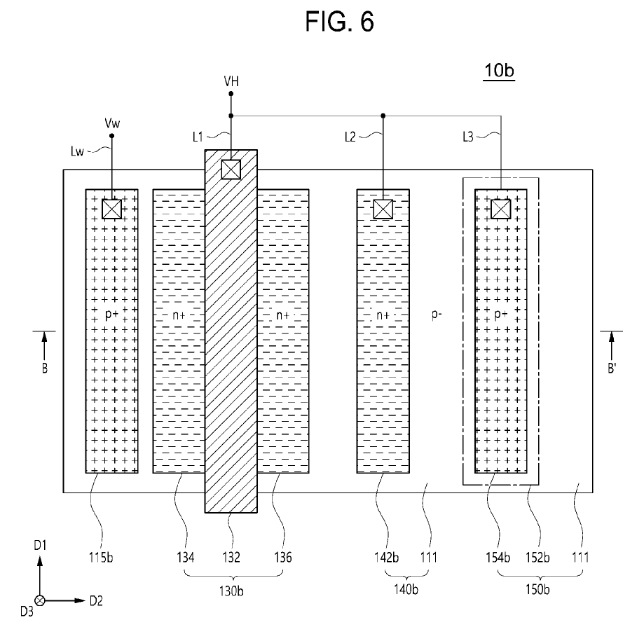

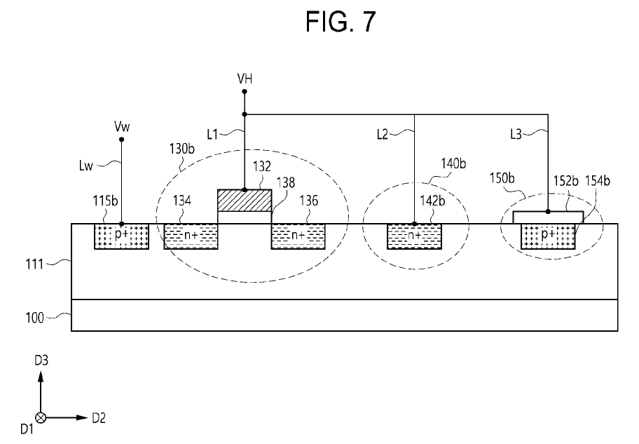

FIG. 5 is a circuit diagram illustrating a PID protection device 10b in accordance with example embodiments. FIG. 6 is a layout diagram illustrating the PID protection device 10b of FIG. 5. FIG. 7 is a cross-sectional view of a semiconductor integrated circuit device taken along a line B-B' of FIG. 5.

Referring to FIGS. 5 to 7, the PID protection device 10b may include a protection transistor 130b, a first discharging element 140b and a second discharging element 150b.

The PID protection device 10b may be integrated into a selected region of the semiconductor substrate 100. The selected region of the semiconductor substrate 100 may include only an expanded p-well 111 without any n-well.

An area of the expanded p-well 111 may be larger than the area of the p-well 110 illustrated in FIGS. 3 and 4, and may be smaller than the combined area of the p-well 110 and the n-well 120 of FIGS. 3 and 4. As a result, an occupied area of the PID protection device 10b may correspond to the area of the expanded p-well 111.

Since the protection transistor 130b, the first discharging element 140b and the p-well pickup region 115b are substantially the same as the configurations of the protection transistor 130a, the first discharging element 140a, and the p-well pickup region 115 of the PID protection device 10a shown in FIGS. 2 to 4, redundant description will be omitted.

The second discharging element 150b may include a blocking pattern 152b, a high concentration p-type impurity region 154b, and the expanded p-well 111.

The blocking pattern 152b may be formed on the expanded p-well 111 to cover the high concentration p-type impurity region 154b. The blocking pattern 152b may be located on the other side of the first discharging element 140b. The blocking pattern 152b may include an insulation layer having a thickness relatively smaller than the gate insulation layer 138. The blocking pattern 152b may be in contact with a third wiring structure L3 electrically connected to the first and second wiring structures L1 and L2. In example embodiments, the blocking pattern 152b may isolate the third wiring structure L3 from the high concentration p-type impurity region 154b.

In some embodiments, the high concentration P-type (p+) impurity region 154b may be formed in the expanded p-well 111. The high concentration P-type (p+) impurity region 154b and the expanded p-well 111 corresponding to the conductive elements of the second charge element 150b may be operated as a pseudo-junction diode, wherein a potential barrier may be formed in accordance with the impurity concentration difference.

An operation of the PID protection device 10b with the above described configuration may be as follows.

In an instance in which the first wiring structure L1 is floated, the protection transistor 130b may be turned off. In this instance, the plasma induced charges introduced along the first wiring structure L1 may be accumulated or trapped in the gate insulation layer 138 of the protection transistor 130b.

The first discharging element 140b may be operated as the reverse diode, so that the plasma induced negative charge introduced through the second wiring structure L2 connected to the first wiring structure L1 may be electro-migrated to the expanded p-well 111.

When the plasma induced positive charge is introduced into the second discharging element 150b via the third wiring structure L3 connected to the first and second wiring structures L1 and L2, the plasma induced positive charge may be tunneled into the blocking pattern 152 and may be electro-migrated to the high concentration P-type (p+) impurity region 154b of the second discharging element 150b. The plasma induced positive charge may be electro-migrated to the expanded p-well 111 by the pseudo-junction diode operation between the high concentration P-type impurity region 154b of the second discharging element 150b and the expanded p-well 111. The pseudo-junction diode operation may denote (for example, include, represent) a band bending that may be generated due to a difference in impurity concentration between the high concentration P-type (p+) impurity region 154b and the expanded p-well 111, resulting in charges being electro-migrated. Accordingly, the plasma inducted positive charge may be discharged through the well pickup line Lw connected with the expanded p-well 111 or through the charged semiconductor substrate 100.

On the other hand, when the gate voltage VH is transmitted to the second discharging element 150b via the third wiring structure L3, the conductive elements of the third wiring structure L3 and the second charge portion 150b, i.e., the pseudo-junction diode, may be electrically isolated by the blocking pattern 152. Therefore, the pseudo-junction diode of the second charge portion 140b may not be operated.

The semiconductor integrated circuit device for discharging the plasma induced charges, in accordance with example embodiments, may include the protection transistor, the first discharging element for discharging the plasma induced negative charge, and the second discharging element for discharging the plasma induced positive charge.

The second discharging element may include the high concentration P-type (p+) impurity region formed in the floated n-well, or the p-well in which the protection transistor and the first discharging element may be integrated, and the blocking pattern configured to cover an upper portion of the high concentration P-type impurity region.

When the high concentration P-type impurity region is formed in the n-well, the n-well may not be needed to be equipped with the n-well pickup region for applying the voltage to the n-well, so that the plasma induced positive charge may be effectively discharged without expanding the area of the semiconductor integrated circuit device.

When the high concentration P-type impurity region is formed in the p-well, the protection transistor and the first discharging element may be formed in the same p-well, thereby reducing the area of the semiconductor integrated circuit device.

On the other hand, when the protection transistor is operated, even if the gate voltage of the protection transistor is applied to the second discharging element, the applying of the gate voltage to the high concentration P-type impurity region may be blocked by the blocking pattern.

As a result, the plasma induced positive and negative charges may be effectively discharged when the protection transistor may not be driven, without increasing the occupying area.

While the example embodiments may illustrate the use of the NMOS transistor as the protection transistor, the same effect may be achieved by configuring the protection transistor as a PMOS transistor, without limitation.

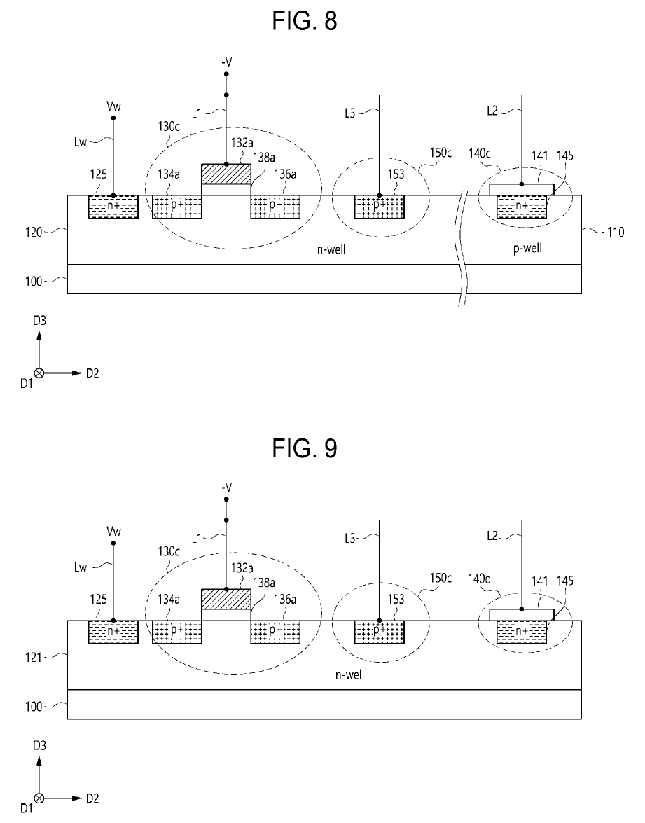

FIGS. 8 and 9 are cross-sectional views illustrating semiconductor integrated circuit devices in accordance with example embodiments.

Referring to FIG. 8, a PID protection device of a semiconductor integrated circuit device may include a protection transistor 130c including a PMOS transistor, a first discharging element 140c and a second discharging element 150c.

In example embodiments, the PID protection device may be integrated into an n-well 120 and a p-well 110 provided in the semiconductor substrate 100. An area of the n-well 120 may have a relatively larger area than an area of the p-well 110. Further, the n-well 120 may include an n-well pickup region 125 including a high concentration of N-type (n+) impurities. The n-well pickup region 125 may be electrically connected with a well pickup line Lw to receive a well voltage Vw, such as a ground voltage. In contrast, the p-well 110 may remain floating without an additional well pickup area.

The protection transistor 130c, that is, the PMOS transistor, may be integrated into the n-well 120. The protection transistor 130c may include a gate 132a in connection with the first wiring structure L1, a source 134a including a high concentration of p-type impurities, and a drain 136a including the high concentration of p-type impurities. The protection transistor 130c may be turned on in response to a gate voltage (-V) provided through the first wiring structure L1. The protection transistor 130c may further include a gate insulation layer 138a configured to insulate between the gate 132a and the n-well 120. The gate insulation layer 138a may be formed with a thickness of about 40μm to about 70μm, to withstand the gate voltage (-V). The first discharging element 140c may be integrated in the p-well 110. The first discharging element 140c may include a blocking pattern 141 and a high concentration N-type impurity region 145. The blocking pattern 141 may have a thickness, for example, less than the gate insulation layer 138a.

The second wiring structure L2 may be connected with the first wiring structure L1, and may be in contact with the blocking pattern 141 of the first discharging element 140c. For example, when the gate voltage (-V) is applied through the first wiring structure L1, even if a leakage current may flow through the second wiring structure L2 connected with the first wiring structure L1, the leakage current may be prevented from entering the blocking pattern 141 into the high concentration n-type impurity region 142.

A reverse diode may be generated between the high concentration N-type impurity region 142 of the first discharging element 140c and the floated p-well 110. Accordingly, the plasma induced negative charge flowing into the high concentration N-type impurity region 142 via the second wiring structure L2 and the blocking pattern 141 may be discharged by an operation of the reverse diode.

The second discharging element 150c may be integrated into the n-well 120 in which the protection transistor 130c may be integrated. The second discharging element 150c may include a high concentration P-type impurity region 153. Accordingly, the forward diode may be generated between the high concentration P-type impurity region and the n-well 120, and the second charge element 150c may perform an operation of the forward diode. Accordingly, when the plasma induced positive charge flowing into the second discharging element 150c via the third wiring structure L3 connected with the first wiring structure L1, a potential of the high-concentration P-type impurity region 153 may become higher than a potential of the n-well 120, and the first discharging element 150c may be turned on. Accordingly, the plasma induced positive charge may be discharged through the n-well 120 configured to receive the well voltage Vw.

In the illustrated embodiment of FIG. 9, a PID protection device may be integrated into an expanded n-well 121 without a p-well. The expanded n-well 121 may receive the well voltage Vw via the well pickup region 125.

The protection transistor 130c and the second discharging element 150c may have the same configuration as in FIG. 8. However, the first discharging element 140d may be integrated into the expanded n-well 121 unlike in FIG. 8.

The first discharging element 140d may include a blocking pattern 141 and a high concentration N-type impurity region 145. The plasma induced negative charge introduced through the third wiring structure L3 may be discharged by the pseudo-junction diode operation between the high concentration N-type impurity region 145 and the expanded n-well 121.

While the present invention has been described in detail with reference to preferred embodiments, the invention is not limited to the above embodiments, but is capable of many modifications by those having ordinary skill in the art within the scope of the technical ideas of the invention.

What is claimed is:

1. A semiconductor integrated circuit device comprising:
a protection transistor connected with a first wiring structure, and configured to receive at least one of a gate voltage and a plasma induced charge;
a first discharging element connected to a second wiring structure electrically connected with the first wiring structure, and configured to discharge a plasma inducted negative charge introduced through the second wiring structure; and
a second discharging element configured to discharge a plasma induced positive charge via a third wiring structure electrically connected to the second wiring structure,
wherein at least one of the first discharging element and the second discharging element comprises a blocking pattern configured to block a leakage current in accordance with the gate voltage during operation of the protection transistor.

2. The semiconductor integrated circuit device of claim 1, further comprising:
a semiconductor substrate;
a first well having a first conductive type located in a selected region of the semiconductor substrate, the protection transistor and the first discharging element being integrated into the first well; and
a second well having a second conductive type opposite to the first conductive type, located on the semiconductor substrate adjacent to the first well, the second discharging element being integrated in the second well,
wherein the second well is floated.

3. The semiconductor integrated circuit device of claim 2, wherein the first well comprises a well pickup region including a high concentration impurity of the first conductive type configured to receive a well voltage.

4. The semiconductor integrated circuit device of claim 2,
wherein the second discharging element comprises a high concentration first conductive type impurity region formed in the second well, and
wherein the blocking pattern is interposed between the high concentration first conductive impurity region and the third wiring structure, and the blocking pattern comprises an insulation pattern having a thickness less than a gate insulation layer of the protection transistor.

5. The semiconductor integrated circuit device of claim 2,
wherein the first discharging element comprises a high concentration first conductive type impurity region formed in the second well, and
wherein the blocking pattern is interposed between the high concentration first conductive type impurity region and the second wiring structure and the blocking pattern comprises an insulation pattern having a thickness less than a gate insulation layer of the protection transistor.

6. The semiconductor integrated circuit device of claim 1, further comprising:
a semiconductor substrate; and
an expanded first well having a first conductive type located in a selected region of the semiconductor substrate, the protection transistor, the first discharging element and the second discharging element being integrated in the expanded first well,
wherein the expanded first well comprises a well pickup region, including a high concentration impurity of the first conductive type, configured to receive a well voltage.

7. The semiconductor integrated circuit device of claim 6,
wherein the second discharging element comprises a high concentration first conductive impurity region formed in the first well, and
wherein the blocking pattern is interposed between the high concentration first conductive impurity region and the third wiring structure and the blocking pattern has a thickness less than a gate insulation layer of the protection transistor.

8. The semiconductor integrated circuit device of claim 6,
wherein the first discharging element comprises a high concentration first conductive type impurity region formed in the first well, and
wherein the blocking pattern is interposed between the high concentration first conductive impurity region and the second wiring structure and the blocking pattern comprises an insulation pattern having a thickness less than a gate insulation layer of the protection transistor.

9. The semiconductor integrated circuit device of claim 1, wherein the first discharging element comprises a reverse diode.

10. The semiconductor integrated circuit device of claim 1, wherein the second discharging element comprises a forward diode.

11. A semiconductor integrated circuit device comprising:
a semiconductor substrate;
a first well having a first conductive type formed in the semiconductor substrate;
a protection transistor integrated into the first well;
a first discharging element including a reverse diode formed in the first well; and
a second discharging element including a pseudo-junction diode formed in the first well and a blocking pattern having an insulating material configured to cover the pseudo-junction diode.

12. The semiconductor integrated circuit device of claim 11, wherein the first discharging element comprises a high concentration impurity region having a second conductive type formed in the first well, and wherein the second conductive type is opposite to the first conductive type.

13. The semiconductor integrated circuit device of claim 11, wherein the second discharging element comprises a high concentration impurity region having the first conductive type formed in the first well.

14. The semiconductor integrated circuit device of claim 11, further comprising:
a first wiring structure configured to deliver a gate voltage to a gate of the protection transistor;
a second wiring structure electrically coupled to the first wiring structure and coupled to the first discharging element; and
a third wiring structure connected to the first and second wiring structures and in contact with the blocking pattern of the second discharging element.

15. The semiconductor integrated circuit device of claim 11, wherein the first well further comprises a well pickup region configured to receive a well voltage.

16. The semiconductor integrated circuit device of claim 11, wherein the blocking pattern has a thickness less than a thickness of a gate insulation layer of the protection transistor.

17. The semiconductor integrated circuit device of claim 11, wherein the semiconductor substrate is charged.

18. A semiconductor integrated circuit device comprising:
a charged semiconductor substrate;
a first well having a first conductive type formed in the semiconductor substrate;
a second well having a second conductive type formed in the semiconductor substrate adjacent to the first well;
a protection transistor formed in the first well;
a first discharging element including a reverse diode formed in the first well; and
a second discharging element including a forward diode formed in the second well, and a blocking pattern having an insulating material configured to cover the forward diode.

19. The semiconductor integrated circuit device of claim 18, wherein the first discharging element comprises a high concentration impurity region having a second conductive type formed in the first well, and wherein the second conductive type is opposite to the first conductive type.

20. The semiconductor integrated circuit device of claim 18, wherein the second discharging element comprises a high concentration impurity region having the first conductive type formed in the second well.

21. The semiconductor integrated circuit device of claim 18, further comprising:
a first wiring structure configured to deliver a gate voltage to a gate of the protection transistor;
a second wiring structure electrically coupled to the first wiring structure, and coupled to the first discharging element; and
a third wiring structure connected to the first and second wiring structures and in contact with the blocking pattern of the second discharging element.

22. The semiconductor integrated circuit device of claim 18, wherein the second well is floated.

23. The semiconductor integrated circuit device of claim 18, wherein the blocking pattern has a thickness less than a thickness of a gate insulation layer of the protection transistor.
